(19) United States
(12) Patent Application Publication
(10) Pub. No.: US 2021/0210578 A1
(43) Pub. Date: Jul. 8, 2021

(54) AMOLED DISPLAY AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Caiqin CHEN, Wuhan, Hubei (CN)

(21) Appl. No.: 16/091,112

(22) PCT Filed: Aug. 16, 2018
(86) PCT No.: PCT/CN2018/100741

§ 371 Date: Oct. 4, 2018

(30) Foreign Application Priority Data
Jun. 12, 2018 (CN) 201810601417.1

(51) Int. Cl. H01L 27/32; H01L 51/56

(52) U.S. Cl. CPC H01L 27/3272; H01L 2227/323; H01L 51/56

(57) ABSTRACT

An active-matrix organic light emitting diode (AMOLED) display and a manufacturing method thereof are provided. The method includes sequentially forming a shielding layer, a buffer layer, an active layer, a first gate insulating layer, a first gate electrode, a second gate insulating layer, a second gate electrode, and an insulating interlayer on a substrate; patterning the insulating interlayer using a mask; and sequentially forming a source/drain electrode, a flat layer, an anode, a pixel defining layer, and a photoresist spacer on the insulating interlayer.

### BACKGROUND

### 1. Field of the Disclosure

The present disclosure relates to display technologies, and more particularly to an active-matrix organic light emitting diode (AMOLED) display and a manufacturing method thereof.

### 2. Description of Related Art

A structure of AMOLED display includes a cover plate 11, an ink frame layer 12, a first adhering layer 13, a polymer layer 14, a touch sensing layer 15, a second adhering layer 16, a package layer 17, an organic light emitting layer 18, a thin-film transistor (TFT) substrate 19, a support layer 20, a buffer layer 21, an insulating layer 22, a graphite layer 23, a copper foil layer 24, and a third adhering layer 25. The third adhering layer 25 is used to adhere the copper foil layer 24 and a main board of the AMOLED display. In the existing AMOLED display, the copper foil layer 24 is disposed between a display screen and the main board. The function of the copper foil layer 24 is to shield signal interferences between the display screen and various functional units (e.g., a battery and a primary memory) on the main board.

In the existing designs, the copper foil layer 24 and the graphene layer 23 above it are adhered together by optical clear adhesive (OCA) glue, or the graphene layer 23 is directly coated on the copper foil layer 24. However, the two approaches will increase manufacturing cost. Further, the thickness of the copper foil layer 24 and/or the OCA glue will increase overall thickness of the AMOLED display.

Therefore, it needs to provide an AMOLED display and a manufacturing method thereof to solve the problems in the existing arts.

### SUMMARY

The objective of the present disclosure is to provide an AMOLED display and a manufacturing method thereof for being able to reduce overall thickness of the display and lower manufacturing cost.

In order to solve above technical problems, the present disclosure provides a method for manufacturing an AMOLED display, including:

forming a shielding layer on a substrate, in which the shielding layer is a metal film layer;

sequentially forming a buffer layer, an active layer, a first gate insulating layer, a first gate electrode, a second gate insulating layer, a second gate electrode, and an insulating interlayer on the shielding layer;

patterning the insulating interlayer using a mask to make the insulating interlayer form two first vias, in which positions of the two first vias correspond to a source electrode and a drain electrode, respectively; and

sequentially forming the source/drain electrode, a flat layer, an anode, a pixel defining layer, and a photoresist spacer on the patterned insulating interlayer, in which the flat layer forms a second via.

In the method of the present disclosure, a material of the shielding layer is Molybdenum.

In the method of the present disclosure, the step of forming the shielding layer on the substrate includes:

forming the shielding layer on the substrate by magnetron sputtering.

In the method of the present disclosure, the two first vias are used to connect the source electrode to the active layer and connect the drain electrode and the active layer, respectively.

In the method of the present disclosure, the second via is used to connect the anode and the drain electrode.

In the method of the present disclosure, the step of forming the first gate electrode on the first gate insulating layer includes:

forming a first metal layer on the first gate insulating layer and patterning the first metal layer to obtain the first gate electrode.

In the method of the present disclosure, the step of forming the shielding layer on the substrate includes:

forming a conductive layer on the flat layer and patterning the conductive layer to obtain the anode.

The present disclosure provides a method for manufacturing an AMOLED display, including:

forming a shielding layer on a substrate;

sequentially forming a buffer layer, an active layer, a first gate insulating layer, a first gate electrode, a second gate insulating layer, a second gate electrode, and an insulating interlayer on the shielding layer;

patterning the insulating interlayer using a mask to make the insulating interlayer form two first vias, in which positions of the two first vias correspond to a source electrode and a drain electrode, respectively; and

sequentially forming the source/drain electrode, a flat layer, an anode, a pixel defining layer, and a photoresist spacer on the patterned insulating interlayer.

In the method of the present disclosure, the shielding layer is a metal film layer.

In the method of the present disclosure, a material of the shielding layer is Molybdenum.

In the method of the present disclosure, the step of forming the shielding layer on the substrate includes:

forming the shielding layer on the substrate by magnetron sputtering.

In the method of the present disclosure, the two first vias are used to connect the source electrode to the active layer and connect the drain electrode and the active layer, respectively.

In the method of the present disclosure,

the flat layer forms a second via, which is used to connect the anode and the drain electrode.

The present disclosure further provides an AMOLED display, including:

a shielding layer, a buffer layer, an active layer, a first gate insulating layer, a first gate electrode, a second gate insulating layer, a second gate electrode, an insulating interlayer, a source/drain electrode, a flat layer, an anode, a pixel defining layer, and a photoresist spacer sequentially disposed on a substrate; and

two first vias through the insulating interlayer, in which positions of the two first vias correspond to a source electrode and a drain electrode, respectively.

In the display of the present disclosure, the shielding layer is a metal film layer.

In the display of the present disclosure, a material of the shielding layer is Molybdenum.

In the display of the present disclosure, the shielding layer is formed on the substrate by magnetron sputtering.

In the display of the present disclosure, the two first vias are used to connect the source electrode to the active layer and connect the drain electrode and the active layer, respectively.

In the display of the present disclosure, the flat layer forms a second via, which is used to connect the anode and the drain electrode.

In the AMOLED display and the manufacturing method of the present disclosure, a shielding layer is added before a first process made to a substrate. This saves a copper foil layer in an existing display device, thereby lowering the manufacturing cost and reducing the thickness of the display device.

### BRIEF DESCRIPTION OF DRAWINGS

FIG. 1 is a structural diagram showing an existing AMOLED display device.

FIG. 2 is a structural diagram showing an existing AMOLED display.

FIG. 3 is a structural diagram showing an AMOLED display according to the present disclosure.

### DETAILED DESCRIPTION OF PREFERRED EMBODIMENTS

The following descriptions for the respective embodiments are specific embodiments capable of being implemented for illustrating the present disclosure with referring to the appending figures. In describing the present disclosure, spatially relative terms such as “upper”, “lower”, “front”, “back”, “left”, “right”, “inner”, “outer”, “lateral”, and the like, may be used herein for ease of description as illustrated in the figures. Therefore, the spatially relative terms used herein are intended to illustrate the present disclosure for ease of understanding, but are not intended to limit the present disclosure. In the appending figures, units with similar structures are indicated by same reference numbers.

FIG. 2 is a structural diagram showing an existing AMOLED display.

As shown in FIG. 2, a method for manufacturing the existing AMOLED display primarily includes the following steps.

In step S101, a buffer layer, an active layer, a first gate insulating layer, a first gate electrode, a second gate insulating layer, a second gate electrode, and an insulating interlayer are sequentially formed on a substrate.

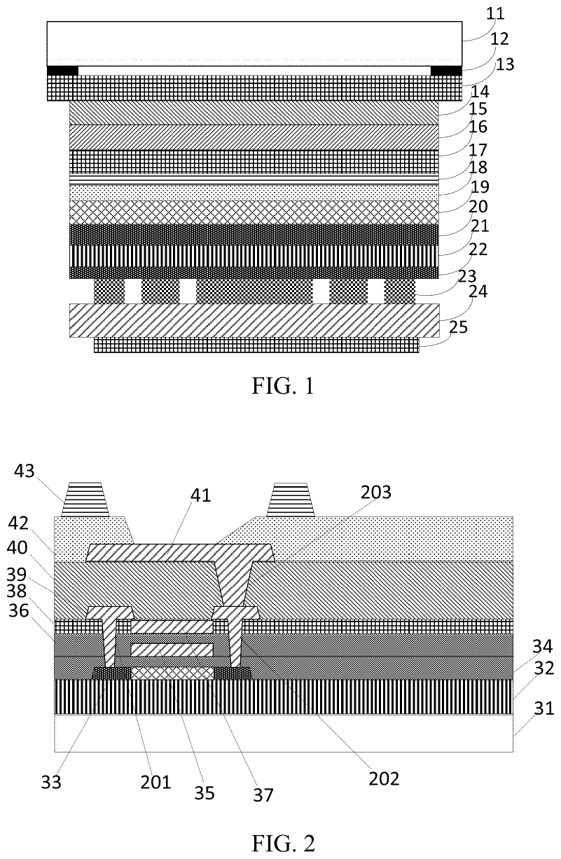

As shown in FIG. 1, the buffer layer 32, the active layer 33, the first gate insulating layer 34, the first gate electrode 35, the second gate insulating layer 36, the second gate electrode 37, and the insulating interlayer 38 are sequentially formed on the substrate 31.

Trenches are formed by patterning the active layer 33 in a mask process. Specifically, exposure and development are made to the active layer 33 using a mask to form the trenches. The positions of the trenches correspond to a source electrode and a drain electrode.

Specifically, manufacture of the first gate electrode is forming a first metal layer on the first gate insulating layer 34 and patterning the first metal layer using a mask to obtain the first gate electrode 35.

Specifically, manufacture of the second gate electrode is forming a second metal layer on the second gate insulating layer 36 and patterning the second metal layer using a mask to obtain the second gate electrode 37.

In step S102, the insulating interlayer is patterned using a mask to make the insulating interlayer located in a display region form two first vias.

The insulating interlayer 38 is patterned using the mask to form the two first vias 201, 202. The position of one of the first vias 201 corresponds to the source electrode and the position of another one of the first vias 201 corresponds to the drain electrode.

In step S103, the source/drain electrode, a flat layer, an anode, a pixel defining layer, and a photoresist spacer are sequentially formed on the patterned insulating interlayer.

Specifically, a third metal layer 39 is formed on the insulating interlayer 38. In one mask process, the third metal layer 39 is patterned to form the source electrode and the drain electrode. The source electrode and the drain electrode are disposed corresponding to the positions of a source hole and a drain hole, respectively.

After that, the flat layer 40 is formed on the third metal layer 39. In one mask process, the flat layer 40 is patterned to form a second via 203.

A conductive layer 41 is formed on the flat layer 40. In one mask process, the conductive layer 41 is patterned to form the anode.

The pixel defining layer 42 and a photoresist spacing layer are formed on the conductive layer 41. In one mask process, the pixel defining layer 42 and the photoresist spacing layer are patterned to form the pixel defining layer 42 and the photoresist spacer 43 with predetermined patterns.

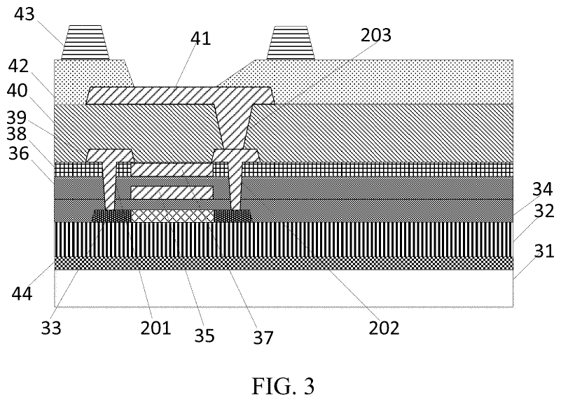

FIG. 3 is a structural diagram showing an AMOLED display according to the present disclosure.

As shown in FIG. 3, a method for manufacturing the AMOLED display of the present disclosure includes the following steps.

In step S201, a shielding layer is formed on a substrate.

For example, the shielding layer 44 is formed on the substrate 31 by magnetron sputtering.

In one embodiment, the shielding layer 44 is a metal film layer.

In one embodiment, in order to better shield signal interferences, a material of the metal film layer is Molybdenum when the shielding layer 44 is the metal film layer. A copper foil in the existing display device is saved by coating a layer of (Mo) metal film on the substrate 31 by PVD magnetron sputtering.

It can be understood that the material of the shielding layer 44 is not limited to a metal material. Other materials with an ability to shield signal interferences can also be used.

In step S202, a buffer layer, an active layer, a first gate insulating layer, a first gate electrode, a second gate insulating layer, a second gate electrode, and an insulating interlayer are sequentially formed on the shielding layer.

As shown in FIG. 3, the buffer layer 32, the active layer 33, the first gate insulating layer 34, the first gate electrode 35, the second gate insulating layer 36, the second gate electrode 37, and the insulating interlayer 38 are sequentially formed on the shielding layer 44.

Trenches are formed by patterning the active layer 33 in a mask process. Specifically, exposure and development are made to the active layer 33 using a mask to form the trenches. The positions of the trenches correspond to a source electrode and a drain electrode. For example, photoresist is coated on the active layer 33 and then the photoresist is processed with the exposure and development using the mask. The trenches are formed after etching the active layer 33.

Specifically, manufacture of the first gate electrode is forming a first metal layer on the first gate insulating layer 34 and patterning the first metal layer using another mask to form the first gate electrode 35.

Specifically, manufacture of the second gate electrode is forming a second metal layer on the second gate insulating layer 36 and patterning the second metal layer using still another mask to form the second gate electrode 37.

In step S203, the insulating interlayer is patterned using a mask to make the insulating interlayer located in a display region form two first vias.

The insulating interlayer 38 is patterned using yet another mask to form the two first vias 201, 202. The position of one of the first vias 201 corresponds to the source electrode and the position of another one of the first vias 201 corresponds to the drain electrode.

For example, photoresist is coated on the insulating interlayer 38 and then the photoresist is processed with exposure and development using the mask to define and form to-be-etched regions. Specifically, the to-be-etched regions correspond to the positions of the two first vias.

In this step, the used mask includes a plurality of transparent regions and a plurality of non-transparent regions. The positions of the transparent regions correspond to the vias, that is, the transparent regions are set corresponding to the positions of the two first vias.

The insulating interlayer 38 corresponding to the to-be-etched regions is etched to form the two first vias 201, 202. The two first vias are used to connect the source electrode to the active layer 33 and connect the drain electrode and the active layer 33, respectively.

In step S204, the source/drain electrode, a flat layer, an anode, a pixel defining layer, and a photoresist spacer are sequentially formed on the patterned insulating interlayer.

Specifically, a third metal layer 39 is formed on the insulating interlayer 38. In one mask process, the third metal layer 39 is patterned to form the source electrode and the drain electrode. The source electrode and the drain electrode are disposed corresponding to the positions of a source hole and a drain hole, respectively.

After that, the flat layer 40 is formed on the third metal layer 39. In one mask process, the flat layer 40 is patterned to form a second via 203. The second via 203 is used to connect the anode and the drain electrode.

A conductive layer 41 is formed on the flat layer 40. In one mask process, the conductive layer 41 is patterned to form the anode.

The pixel defining layer 42 and a photoresist spacing layer are formed on the conductive layer 41. In one mask process, the pixel defining layer 42 and the photoresist spacing layer are patterned to form the pixel defining layer and the photoresist spacer 43 with predetermined patterns.

The present embodiment provides an AMOLED display, which includes a shielding layer 44, a buffer layer 32, an active layer 33, a first gate insulating layer 34, a first gate electrode 35, a second gate insulating layer 36, a second gate electrode 37, an insulating interlayer 38, a source/drain electrode, a flat layer 40, an anode, a pixel defining layer 42, and a photoresist spacer 43 sequentially located on a substrate 31.

For example, the shielding layer 44 is formed on the substrate by magnetron sputtering. For example, magnetron sputtering is used to form the shielding layer 44 on the substrate 31.

In one embodiment, in order to better avoid signal interferences, the shielding layer 44 is a metal film layer. A material of the metal film layer is Molybdenum.

In one embodiment, a copper foil in the existing display device is saved by coating a layer of (Mo) metal film on the substrate 31 by PVD magnetron sputtering.

The first gate electrode 35 is obtained by patterning a first metal layer, the second gate electrode 37 is obtained by patterning a second metal layer, and the source/drain electrode is obtained by patterning a third metal layer 39.

The insulating interlayer 38 located on a display region forms two first vias. The positions of the two first vias 201 and 202 correspond to the source electrode and the drain electrode, respectively. The two first vias 201, 202 are used to connect the source electrode to the active layer 15 and connect the drain electrode to the active layer 33, respectively.

The flat layer 40 forms a second via 203, which is used to connect the anode and the drain electrode.

In the AMOLED display and the manufacturing method of the present disclosure, a shielding layer is added before a first process made to a substrate. This saves a copper foil layer in an existing display device, thereby lowering the manufacturing cost and reducing the thickness of the display device.

Above all, while the preferred embodiments of the present disclosure have been illustrated and described in detail, it is intended that the present disclosure should not be limited to the preferred embodiment. Various modifications and alterations which maintain the spirit and realm of the present disclosure can be made by persons skilled in this art. The protective scope of the present disclosure is subject to the scope as defined in the claims.

1. A method for manufacturing an active-matrix organic light emitting diode (AMOLED) display, comprising:
forming a shielding layer on a substrate, in which the shielding layer is a metal film layer;
sequentially forming a buffer layer, an active layer, a first gate insulating layer, a first gate electrode, a second gate insulating layer, a second gate electrode, and an insulating interlayer on the shielding layer;
patterning the insulating interlayer using a mask to make the insulating interlayer form two first vias, in which positions of the two first vias correspond to a source electrode and a drain electrode, respectively; and
sequentially forming the source/drain electrode, a flat layer, an anode, a pixel defining layer, and a photoresist spacer on the patterned insulating interlayer, in which the flat layer forms a second via.

2. The method according to claim 1, wherein a material of the shielding layer is Molybdenum.

3. The method according to claim 1, wherein the step of forming the shielding layer on the substrate comprises:
forming the shielding layer on the substrate by magnetron sputtering.

4. The method according to claim 1, wherein the two first vias are used to connect the source electrode to the active layer and connect the drain electrode and the active layer, respectively.

5. The method according to claim 1, wherein the second via is used to connect the anode and the drain electrode.

6. The method according to claim 1, wherein the step of forming the first gate electrode on the first gate insulating layer comprises:
forming a first metal layer on the first gate insulating layer and patterning the first metal layer to obtain the first gate electrode.

7. The method according to claim 1, wherein the step of forming the anode on the flat layer comprises:
forming a conductive layer on the flat layer and patterning the conductive layer to obtain the anode.

8. A method for manufacturing an active-matrix organic light emitting diode (AMOLED) display, comprising:
forming a shielding layer on a substrate;
sequentially forming a buffer layer, an active layer, a first gate insulating layer, a first gate electrode, a second gate insulating layer, a second gate electrode, and an insulating interlayer on the shielding layer;
patterning the insulating interlayer using a mask to make the insulating interlayer form two first vias, in which positions of the two first vias correspond to a source electrode and a drain electrode, respectively; and
sequentially forming the source/drain electrode, a flat layer, an anode, a pixel defining layer, and a photoresist spacer on the patterned insulating interlayer.

9. The method according to claim 8, wherein the shielding layer is a metal film layer.

10. The method according to claim 9, wherein a material of the shielding layer is Molybdenum.

11. The method according to claim 8, wherein the step of forming the shielding layer on the substrate comprises:
forming the shielding layer on the substrate by magnetron sputtering.

12. The method according to claim 8, wherein the two first vias are used to connect the source electrode to the active layer and connect the drain electrode and the active layer, respectively.

13. The method according to claim 8, wherein the flat layer forms a second via, which is used to connect the anode and the drain electrode.

14. An active-matrix organic light emitting diode (AMOLED) display, comprising:
a shielding layer, a buffer layer, an active layer, a first gate insulating layer, a first gate electrode, a second gate insulating layer, a second gate electrode, an insulating interlayer, a source/drain electrode, a flat layer, an anode, a pixel defining layer, and a photoresist spacer sequentially disposed on a substrate; and
two first vias through the insulating interlayer, in which positions of the two first vias correspond to a source electrode and a drain electrode, respectively.

15. The display according to claim 14, wherein the shielding layer is a metal film layer.

16. The display according to claim 15, wherein a material of the shielding layer is Molybdenum.

17. (canceled)

18. The display according to claim 14, wherein the two first vias are used to connect the source electrode to the active layer and connect the drain electrode and the active layer, respectively.

19. The display according to claim 14, wherein the flat layer forms a second via, which is used to connect the anode and the drain electrode.
